(19) United States
(12) Patent Application Publication
(10) Pub. No.: US 2011/0221071 A1
(43) Pub. Date: Sep. 15, 2011

(54) ELECTRONIC DEVICE AND MANUFACTURING METHOD OF ELECTRONIC DEVICE

(75) Inventors: Norikazu MOTOHASHI, Kanagawa (JP); Kouji SOEJIMA, Kanagawa (JP); Yoichiro KURITA, Kanagawa (JP)

(73) Assignee: RENESAS ELECTRONICS CORPORATION, Kawasaki-shi (JP)

(21) Appl. No.: 13/045,219

(22) Filed: Mar. 10, 2011

(30) Foreign Application Priority Data
Mar. 12, 2010 (JP) 2010-056019

(51) Int. Cl. H01L 21/84; H01L 23/48

(52) U.S. Cl. 257/774; 438/113; 257/E21.7; 257/E23.01

(57) ABSTRACT

In an electronic device having multilayer resin interconnection layers, it is desired to reduce the warp of its support substrate. It is manufactured by: forming a lower layer including a via and a first insulating part on the support substrate; and forming an intermediate layer including a first interconnection and a second insulating part covering the first interconnection on the lower layer. The lower layer is formed by: forming the first insulating part on a first circuit region and a first region surrounding it; and forming the via on the first circuit region. The intermediate layer is formed by: forming the first interconnection on the first circuit region; forming a film of the second insulation part to cover the lower layer; and removing the second insulating part on the first region such that an outer circumferential part of an upper surface of the lower layer part is exposed.

This Patent Application is based on Japanese Patent Application No. 2010-056019. The disclosure of the Japanese Patent Application is incorporated herein by reference.

### BACKGROUND OF THE INVENTION

1.Field of the Invention

The present invention relates to an electronic device having a multilayer interconnection substrate and a manufacturing method of an electronic device.

2.Description of Related Art

There is an interconnection substrate called a multi-layer interconnection substrate in which interconnections are laminated to increase the packaging density. In recent years, various investigations are implemented to the multilayer interconnection substrate. For example, Japanese Patent Application Publication JP-A-Heisei 6-244552 discloses a thin-film multilayer interconnection substrate in which insulating thin-film materials are fixedly laminated on an insulating substrate. The thin-film multilayer interconnection substrate is characterized in that insulating thin-film layers are laminated and adhered so that an area of a second insulating thin-film layer laminated on a first insulating thin-film layer on the insulating substrate is made smaller than that of the first insulating thin-film layer, an area of a third insulating thin-film layer laminated on the second insulating thin-film layer is made smaller than that of the second insulating thin-film layer, and areas of subsequent layers after a third insulating thin-film layer are made smaller in turn. Such thin-film multilayer interconnection substrate can suppress warp and delamination of the thin-film multilayer interconnection substrate by decreasing size of the laminated insulating thin-film layers as they are away from the insulating substrate.

The Japanese Patent No.4206885 relates to a manufacturing method of a system-in-package semiconductor device, in which a method for forming a multilayer interconnection on a semiconductor chip is disclosed. According to the manufacturing method of the semiconductor device, electronic circuits corresponding to a plurality of semiconductor chips are formed on a semiconductor wafer and electrodes for deriving from the electronic circuits are formed on a surface of the semiconductor wafer. After the electrodes are formed, a first resin layer is patterned on a surface of the semiconductor wafer with scribe lines left. Then, a first interconnection layer is patterned on the first resin layer, the first resin layer and the first interconnection layer are coated and a second resin layer is patterned with the scribe lines left. After the second resin layer is patterned, the semiconductor wafer is cut along the scribe lines. In the step of forming the second resin layer, the second resin layer is formed to have a smaller area than the first resin layer so that side surfaces and upper surfaces of the first resin layer and the second resin layer are formed stepwise. According to such a manufacturing method of the semiconductor device, since the stress applied to the semiconductor wafer in a stage before dicing is small, warp can be suppressed.

Concerning such multilayer interconnection construct, Japanese Patent Application Publication JP-A-Heisei 6-209165 discloses a technique of a high-density mounting multilayer interconnection structure using a polyimide resin as an interlayer insulating film. In the multilayer interconnection structure, a 2n-th polyimide insulating film is formed so as to cover an end surface of a (2n−1)-th polyimide insulating film, and end surfaces of the 2n-th polyimide insulating film and a (2n+2)-th polyimide insulating film are formed like a step extending downwardly and outwardly.

### SUMMARY

Some electronic devices having a multilayer interconnection substrate are manufactured through a step of building up a resin interconnection layer including an interconnection and insulating resin on a support substrate and a step of mounting a semiconductor chip on the resin interconnection layer. However, in such electronic devices, during a heating step, warp may occur in the support substrate due to shrinkage on curing of the insulating resin in the resin interconnection layer, a thermal expansion coefficient difference between the support substrate and the resin interconnection layer. Warp of the support substrate disadvantageously causes an absorbing error and a transporting error in a stage for mounting a semiconductor chip, and lowering reliability of interconnection.

According to an aspect of the present invention, a manufacturing method of an electronic device includes: forming a lower layer part including a conductive via and a first insulating part covering the via on a support substrate; and forming an intermediate layer part including a first interconnection electrically connected to the via and a second insulating part covering the first interconnection on the lower layer part. The forming the lower layer part includes: forming the first insulating part on a first circuit formation region for forming a circuit and a first region surrounding the first circuit formation region; and forming the via on the first circuit formation region. The forming the intermediate layer part includes: forming the first interconnection on the first circuit formation region; forming a film of the second insulation part to cover the lower layer part; and removing the second insulating part on the first region such that an outer circumferential part of an upper surface of the lower layer part is exposed.

According to another aspect of the present invention, an electronic device includes: a lower layer part including a conductive via and a first insulating part covering the via such that the via is exposed at an upper surface and a lower surface; a circuit layer part including: a laminated interconnection layer formed on the lower layer part and electrically connected to the exposed upper surface of the via; and a laminated insulating layer covering the interconnection layer; a semiconductor chip mounted on the circuit layer part and electrically connected to the interconnection layer. A mold resin part covering: a first outer circumferential part located at an outer circumferential edge of an upper surface of the lower layer part; the circuit layer part; and the semiconductor chip. The circuit layer part is formed on an inner side of the lower layer part in a planar view. The lower layer part is thinner than the circuit layer part.

According to the manufacturing method of an electronic device of the present invention, warp of a support substrate can be reduced even when a resin interconnection layer is built up on the support substrate to form a multilayer interconnection substrate.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a sectional view of an electronic device 1 according to a first embodiment of the present invention;

FIG. 2 is a partial plan view of a wafer-shaped support substrate 100 used to manufacture an interconnection substrate 2;

FIG. 3 is a sectional view showing that a lower layer part 10 is formed on the support substrate 100;

FIG. 4 is a sectional view showing that a plurality of interconnections 31 are formed on the lower layer part 10 in FIG. 3;

FIG. 5 is a sectional view showing that an insulating part 32 is formed so as to cover the lower layer part 10 and the plurality of interconnections 31 in FIG. 4;

FIG. 6 is a sectional view showing that the insulating part 32 above a scribe line 120 is removed from the insulating part 32 in FIG. 5;

FIG. 7 is a sectional view showing that a surface layer of the insulating part 32 in FIG. 6 is removed;

FIG. 8 is a sectional view showing that a part of a plurality of interconnections 41 is formed on an intermediate layer part 30 in FIG. 7;

FIG. 9 is a sectional view showing that an insulating part 42 is formed so as to cover a plurality of seed parts 43 and a plurality of interconnections 44 in FIG. 8;

FIG. 10 is a sectional view showing that a plurality of connecting terminals 45 are formed in FIG. 9;

FIG. 11 is a sectional view showing that a semiconductor chip 3 is mounted on an upper layer part 40 in FIG. 10;

FIG. 12 is a sectional view showing that a mold resin part 5 covering the interconnection substrate 2 and the semiconductor chip 3 in FIG. 11 is formed and the support substrate 100 is removed;

FIG. 13 shows individually separated electronic devices 1;

FIG. 14 is a sectional view of an electronic device 6 according to a second embodiment of the present invention;

FIG. 15 is a plan view showing that the intermediate layer part 30 is formed on the lower layer part 10;

FIG. 16 is a diagram showing that a part of a plurality of interconnections 51 is formed on the intermediate layer part 30 and in a circuit formation region 130 in FIG. 15;

FIG. 17 is a sectional view showing that an insulating part 52 is formed so as to cover a plurality of seed parts 53 and a plurality of interconnections 54 in FIG. 16;

FIG. 18 is a sectional view showing that a plurality of connecting terminals 55 are formed in FIG. 17; and

FIG. 19 is a sectional view of an electronic device 8 according to a third embodiment of the present invention.

### DESCRIPTION OF THE PREFERRED EMBODIMENTS

An electronic device and a manufacturing method of the electronic device according to embodiments of the present invention will be described below referring to the accompanying drawings.

(First Embodiment)

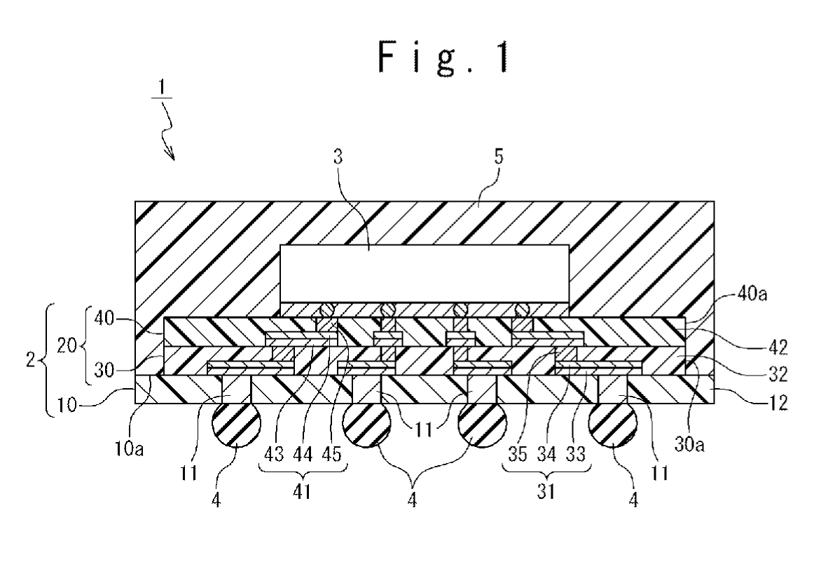

FIG. 1 is a sectional view of an electronic device 1 according to a first embodiment of the present invention. Referring to FIG. 1, the electronic device 1 includes an interconnection substrate 2, a semiconductor chip 3, a plurality of conductive balls 4 and a mold resin part 5.

The interconnection substrate 2 is a multilayer interconnection substrate including a lower layer part 10 and a circuit layer part 20. The lower layer part 10 mounts the plurality of conductive balls 4 thereon and is a lowermost layer of the interconnection substrate 2. The lower layer part 10 has a plurality of conductive vias 11 and an insulating part 12. The vias 11 are exposed on an upper surface and a lower surface of the lower layer part 10 and the exposed lower sides each are electrically connected to the conductive ball 4. The insulating part 12 covers the plurality of vias 11 to protect each of the vias 11 so as to expose the vias 11 on the upper surface and the lower surface thereof. Here, an outer circumferential part 10a on the upper surface of the lower layer part 10 is not covered with the circuit layer part 20 and is covered with the mold resin part 5. That is, the outer circumferential part 10a is located on an outer side of a side surface 30a and a side surface 40a of the circuit layer part 20. In other words, the circuit layer part 20 is formed on an inner side of the lower layer part 10 in a plan view.

The circuit layer part 20 includes a circuit for connecting the semiconductor chip 3 to an external device (not shown). The circuit layer part 20 includes laminated interconnection layers (interconnections 31 and interconnections 41) that are formed on the upper surface of the lower layer part 10 and electrically connected to each of the plurality of vias 11 exposed from the upper surface of the lower layer part 10 and laminated insulating layers (an insulating part 32 and an insulating part 42) that cover the interconnection layers. The insulating layers are laminated so that the thickness of one layer of the insulating layers is not twice as much as that of other layer or more. The insulating layers of the circuit layer part 20 and the insulating part 12 of the lower layer part 10 are made of a material having the same thermal expansion coefficient.

The circuit layer part 20 includes an intermediate layer part 30 and an upper layer part 40. The intermediate layer part 30 is formed on the lower layer part 10. The upper layer part 40 is formed on the intermediate layer part 30 and mounts the semiconductor chip 3 thereon. The intermediate layer part 30 includes a plurality of interconnections 31 and the insulating part 32 covering the plurality of interconnections 31. Each of the plurality of interconnections 31 is an interconnection connected to the via 11 and the interconnection 41 of the upper layer part 40, and includes a seed part 33, an interconnection 34 and a post 35. The upper layer part 40 includes the plurality of interconnections 41 and the insulating part 42 covering the plurality of interconnections 41. Each of the plurality of interconnections 41 is an interconnection connected to the interconnection 31 of the intermediate layer part 30 and the semiconductor chip 3, and includes a seed part 43, an interconnection 44 and a connecting terminal 45. Here, the circuit layer part 20 covers the lower layer part 10 except for the outer circumferential part 10a on the upper surface of the lower layer part 10. That is, the side surface 30a and the side surface 40a of the circuit layer part 20 are located on the inner side of the lower layer part 10 and are covered with the mold resin part 5. In other words, the outer circumferential part 10a, the side surface 30a and the side surface 40a, and an upper surface of the circuit layer part 20 are formed stepwise. In the interconnection substrate 2, a thickness of the lower layer part 10 is smaller than that of the circuit layer part 20.

The semiconductor chip 3 includes a circuit for realizing a desired function. The semiconductor chip 3 is mounted on the circuit layer part 20 and is electrically connected to the interconnection layers in the circuit layer part 20. Each of the plurality of conductive balls 4 are a terminal for connection to an external device. Each conductive ball 4 is mounted on a lower surface of the interconnection substrate 2 and is connected to each via 11. The mold resin part 5 covers the outer circumferential part 10a located on an outer circumferential edge of the upper surface of the lower layer part 10, the circuit layer part 20 and the semiconductor chip 3 to protect them against external factors. The mold resin part 5 is made of an epoxy resin containing filler, which is relatively harder than the insulating part 12, the insulating part 32 and the insulating part 42 in the interconnection substrate 2. Accordingly, an interface between the step-like interconnection substrate 2 and the mold resin part 5 becomes an interface between a resin containing filler and a resin containing no filler.

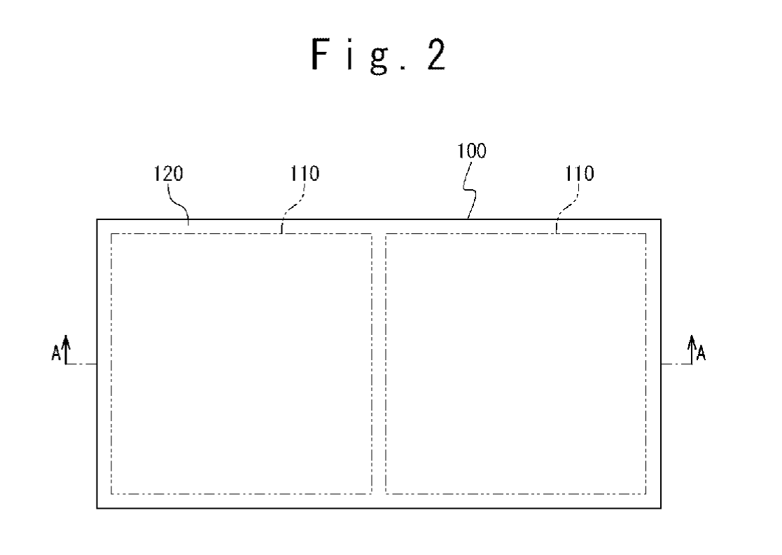

Next, referring to FIGS. 2 to 13, a manufacturing method of the electronic device 1 according to the first embodiment of the present invention will be described.

FIG. 2 is a partial plan view of a wafer-shaped support substrate 100 used to manufacture the interconnection substrate 2. Referring to FIG. 2, the support substrate 100 includes a circuit formation region 110 for forming a circuit and a scribe line 120 surrounding the circuit formation region 110. The scribe line 120 is a region cut in a later step to individually separate the electronic device 1. Since all of the region surrounding the circuit formation region 110 is represented as the scribe line 120 in FIG. 2, all of the region need not constitute the scribe line 120. The support substrate 100 is a substrate for building up the interconnection substrate 2 and is, for example, a ceramic substrate made of silicon or a metallic substrate.

Forming step of the lower layer part 10:

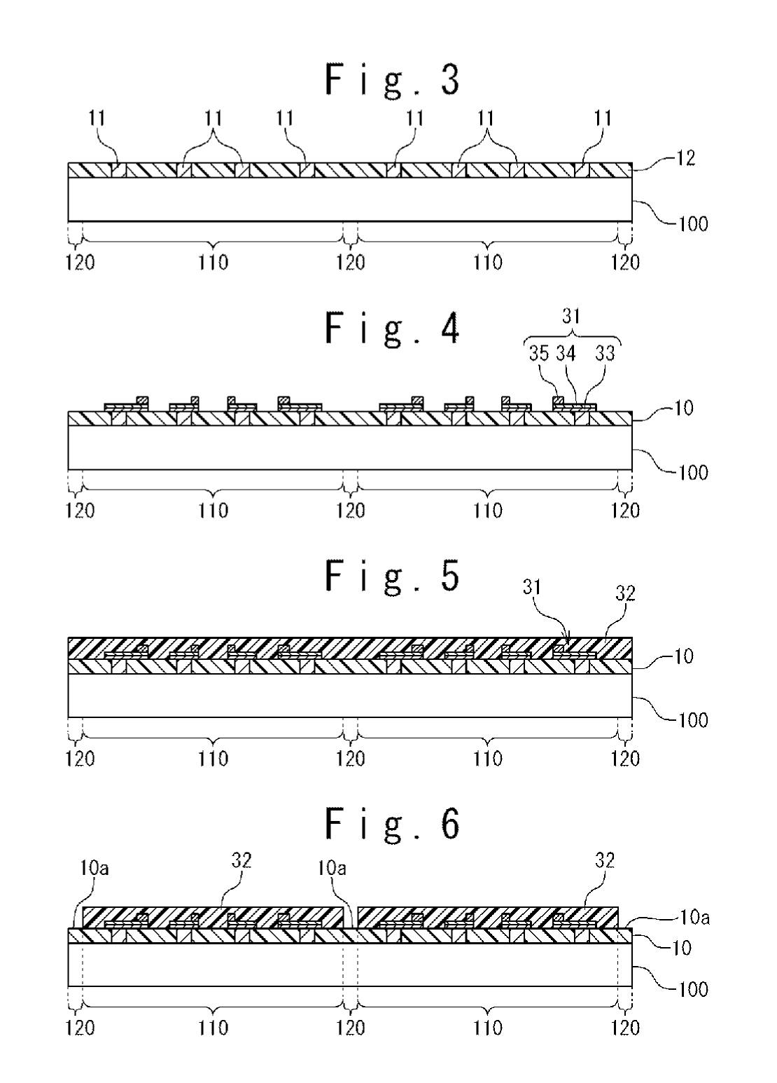

The lower layer part 10 including the plurality of vias 11 and the insulating part 12 covering the plurality of vias 11 is formed on the support substrate 100. FIG. 3 is a sectional view showing that the lower layer part 10 is formed on the support substrate 100. FIG. 3 corresponds to a cross-section taken along A-A in FIG. 2. Referring to FIG. 3, a forming method of the lower layer part 10 will be described. The insulating part 12 made of an insulating resin such as polyimide is formed on the support substrate 100, that is, between the circuit formation region 110 for forming the circuit and the scribe line 120. The insulating part 12 formed on the support substrate 100 has a plurality of via holes in the circuit formation region 110. When describing an example of a forming method of the insulating part 12, the liquid insulating part 12 is applied by spin coating and prebaked. After that, the plurality of vias 11 are formed on the insulating part 12. When the insulating part 12 is made of photosensitive resin, the insulating part 12 is exposed based on a pattern of the plurality of vias 11 and is cured through development and postbaking. The insulating part 12 may be formed of a dry film. When the insulating part 12 is formed, a conductive material such as Cu/Ni is filled into the plurality of via holes to form the plurality of vias 11 in the circuit formation region 110. Through this step, the plurality of vias 11 are formed in the circuit formation region 110 to be exposed on the upper surface and the lower surface of the insulating part 12.

Forming step of the intermediate layer part 30:

The intermediate layer part 30 including the plurality of interconnections 31 electrically connected to the plurality of vias 11, respectively, and the insulating part 32 covering the plurality of interconnections 31 is formed on the lower layer part 10. FIG. 4 is a sectional view showing that the plurality of interconnections 31 are formed on the lower layer part 10 in FIG. 3. Referring to FIG. 4, a forming method of the plurality of interconnections 31 will be described. The plurality of interconnections 31 are formed in the circuit formation region 110 so as to be electrically connected to the respective vias 11. When describing an example of the forming method of the plurality of interconnections 31, a seed layer becoming the plurality of seed parts 33 is formed on the insulating part 12. The seed layer is made of Cu/Ti, becomes an electrode when the plurality of interconnections 34 are formed and is formed by sputtering. A photoresist of a predetermined pattern is formed on the seed layer. Using the photoresist as a mask, the plurality of interconnections 34 are formed by Cu plating. After that, the photoresist is peeled with an organic solvent and the seed layer containing no interconnection 34 in the upper layer is etched. As a result, plural pairs of the seed parts 33 and the interconnections 34 in FIG. 4 are formed. Each of the plurality of posts 35 is formed at a predetermined position on each of the interconnections 34. The plurality of posts 35 are made of Cu, for example, and like the plurality of interconnections 34, are formed by photolithography. Through this step, the plurality of interconnections 31 are formed in the circuit formation region 110.

The insulating part 32 is formed so as to cover the lower layer part 10 and the plurality of interconnections 31. Then, the insulating part 32 above the scribe line 120 is removed so as to expose the outer circumferential part 10a on the upper surface of the lower layer part 10. FIG. 5 is a sectional view showing that the insulating part 32 is formed so as to cover the lower layer part 10 and the plurality of interconnections 31 in FIG. 4. FIG. 6 is a sectional view showing that the insulating part 32 above the scribe line 120 is removed from the insulating part 32 in FIG. 5. Referring to FIGS. 5 and 6, a forming method of the insulating part 32 will be described. As shown in FIG. 5, the insulating part 32 made of a photosensitive resin is applied so as to cover the lower layer part 10 and the plurality of interconnections 31 and then, is prebaked. As shown in FIG. 6, the insulating part 32 is exposed based on a pattern of the scribe line 120 and cured through development and postbaking. The developed insulating part 32 above the scribe line 120 is removed, while the lower layer part 10 (outer circumferential part 10a) located below the removed insulating part 32 remains without being removed. Accordingly, through this step, the support substrate 100 is not exposed. Here, the insulating part 32 has a smaller area than the lower layer part 10, which advantageously reduces warp of the support substrate 100 due to cure shrinkage on curing. The insulating part 32 may be made of the same material as that for the insulating part 12.

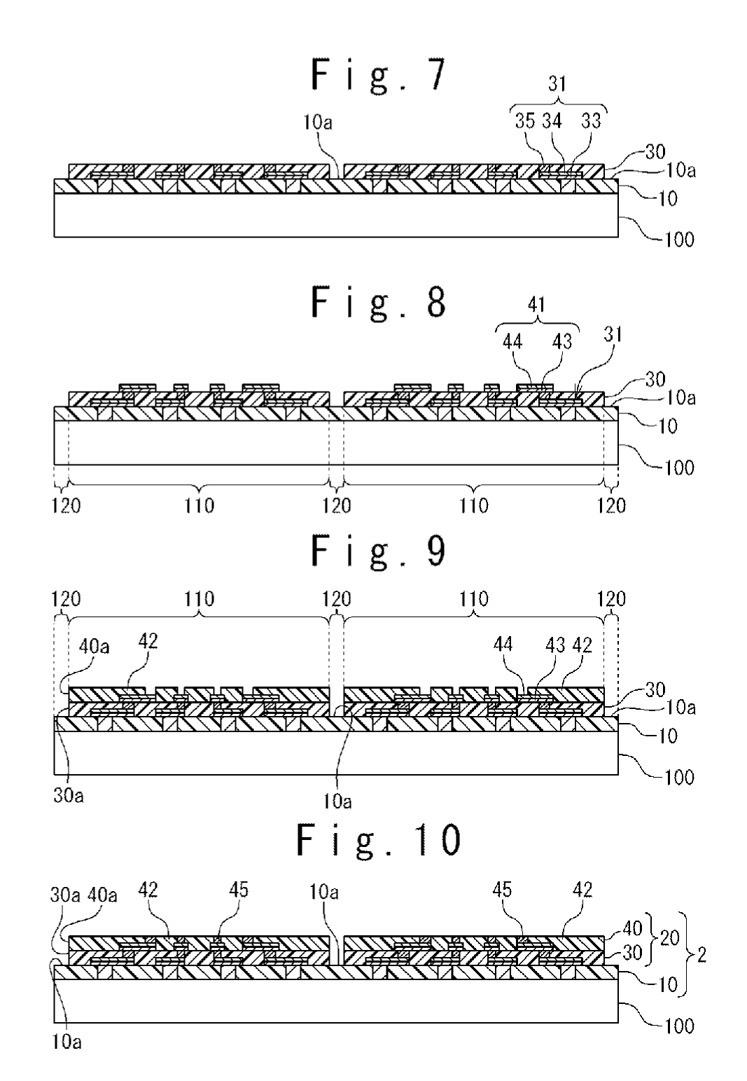

A surface layer of the insulating part 32 is removed to expose the plurality of posts 35 on the upper surface. FIG. 7 is a sectional view showing that the surface layer of the insulating part 32 in FIG. 6 is removed. Referring to FIG. 7, a forming method of the insulating part 32 will be described. The surface of the insulating part 32 is polished by CMP (Chemical Mechanical Polishing). The surface of the insulating part 32 is flattened by polishing to expose the plurality of posts 35 on the upper surface. Here, the lower layer part 10 and the intermediate layer part 30 form a step in which the intermediate layer part 30 is smaller than the lower layer part 10. Through these above-mentioned steps, the intermediate layer part 30 is formed.

Forming step of the upper layer part 40: The upper layer part 40 having the plurality of interconnections 41 electrically connected to the plurality of interconnections 31, respectively, and the insulating part 42 covering the plurality of interconnections 41 are formed on the intermediate layer part 30. FIG. 8 is a sectional view showing that a part of the plurality of interconnections 41 is formed on the intermediate layer part 30 in FIG. 7. Referring to FIG. 8, a forming method of the plurality of interconnections 41 will be described. The plurality of interconnections 41 are formed in the circuit formation region 110 so as to be electrically connected to the respective interconnections 31. The same forming method of the seed parts 43 and the interconnections 44 as the above-mentioned forming method of the interconnections 31 is exemplified.

The insulating part 42 made of the same material as that for the insulating part 32 is formed on the intermediate layer part 30. The insulating part 42 has a plurality of via holes in the circuit formation region 110. FIG. 9 is a sectional view showing that the insulating part 42 is formed so as to cover the plurality of seed parts 43 and the plurality of interconnections 44 in FIG. 8. Referring to FIG. 9, a step of forming the insulating part 42 will be described. The insulating part 42 is formed so as to cover the outer circumferential part 10a on the upper surface of the lower layer part 10 and the intermediate layer part 30. Then, the insulating part 42 above the scribe line 120 is removed so as to expose the outer circumferential part 10a. When describing an example of a forming step of the insulating part 42, the insulating part 42 is applied so as to cover the lower layer part 10, the intermediate layer part 30, the plurality of seed parts 43 and the plurality of interconnections 44 and then, are prebaked. The prebaked insulating part 42 is exposed based on the pattern of the scribe line 120 and patterns of the plurality of connecting terminals 45 connected to the semiconductor chip 3 and is cured through development and postbaking. Referring to FIG. 9, the insulating part 42 above the scribe line 120 is removed through development to expose the outer circumferential part 10a of the lower layer part 10. At this time, the insulating part 42, like the insulating part 32, has a smaller area than the lower layer part 10, which advantageously reduces warp of the support substrate 100 due to shrinkage on curing. The cured insulating part 12 and insulating part 32 each have a thermal expansion coefficient that is different from that of the support substrate 100. However, since the insulating part 32 is formed smaller, warp of the support substrate 100 due to the difference in thermal expansion coefficient is reduced.

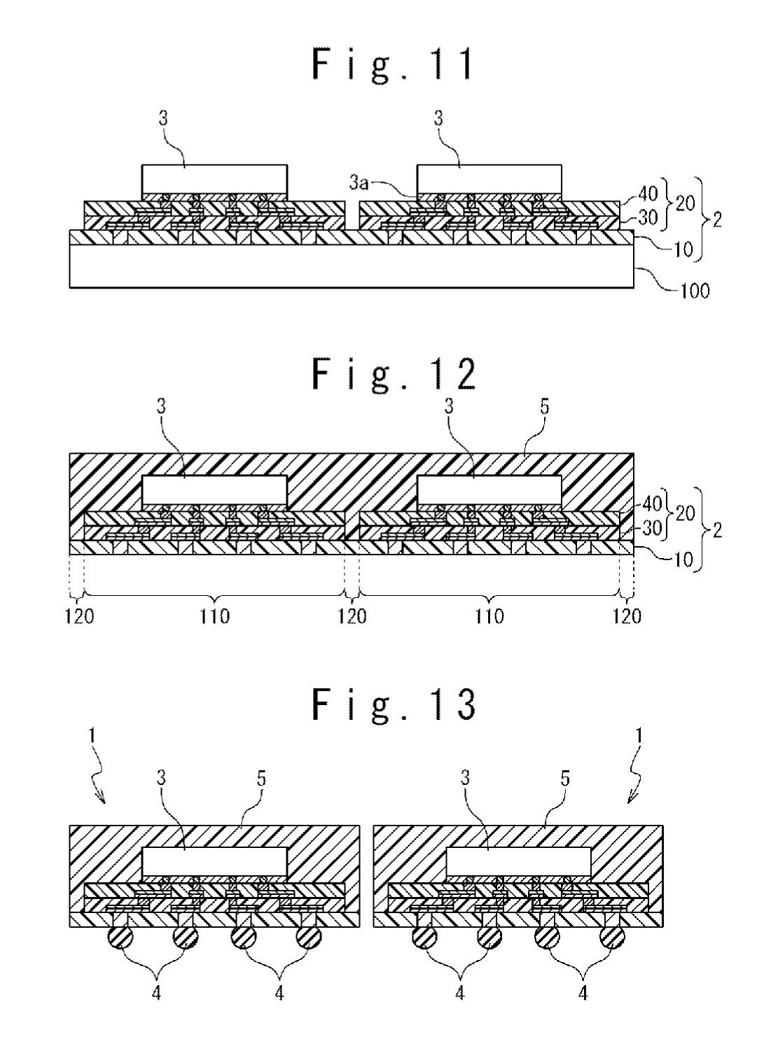

A conductive material such as Ni/Au is filled into the plurality of via holes to form the plurality of connecting terminals 45 in the circuit formation region 110. FIG. 10 is a sectional view showing that the plurality of connecting terminals 45 are formed in FIG. 9. Referring to FIG. 10, the interconnection substrate 2 is built up on the support substrate 100. In the interconnection substrate 2, the lower layer part 10 and the circuit layer part 20 that is smaller than the lower layer part 10 are formed stepwise. That is, the outer circumferential part 10a, the side surface 30a and the side surface 40a, and the upper surface of the upper layer part 40 are formed stepwise. Through these steps, the upper layer part 40 is formed.

Mounting step of the semiconductor chip 3:

The semiconductor chip 3 electrically connected to the connecting terminals 45 is formed on the upper layer part 40. FIG. 11 is a sectional view showing that the semiconductor chip 3 is mounted on the upper layer part 40 in FIG. 10. Referring to FIG. 11, a mounting method of the semiconductor chip 3 will be described. The electronic device shown in FIG. 10 is transported to a place where the semiconductor chip 3 is mounted. At this time, since warp of the support substrate 100 is reduced, the electronic device shown in FIG. 10 can be accurately transported to the mounting place of the semiconductor chip 3 without causing any transporting error. The semiconductor chip 3 is mounted so as to electrically connect the electronic circuit in the semiconductor chip 3 to the connecting terminals 45 of the upper layer part 40 in the electronic device. Then, an underfill 3a for reinforcing connection is filled between the upper layer part 40 and the semiconductor chip 3.

Resin sealing step, removing step of the support substrate 100:

The interconnection substrate 2 and the semiconductor chip 3 are covered with the mold resin part 5. After that, the support substrate 100 is removed from the lower layer part 10. FIG. 12 is a sectional view showing that the mold resin part 5 covering the interconnection substrate 2 and the semiconductor chip 3 in FIG. 11 is formed and the support substrate 100 is removed. Referring to FIG. 12, a forming method of the mold resin part 5 and removal of the support substrate 100 will be described. The electronic device shown in FIG. 11 is transported to a place where the mold resin part 5 is formed. At this time, since warp of the support substrate 100 is reduced, the electronic device shown in FIG. 11 can be accurately transported to the forming place of the mold resin part 5 without causing any transporting error. The mold resin part 5 is formed so as to cover the outer circumferential part 10a on the upper surface of the lower layer part 10, the intermediate layer part 30, the upper layer part 40 and the semiconductor chip 3. After mold resin part 5 is cured, the support substrate 100 is removed. At this time, since the lower layer part 10 on the support substrate 100 is not divided by the scribe line 120, when the support substrate 100 is removed, a force exerted on an interface between the lower layer part 10 and the circuit layer part 20 can be dispersed, thereby preventing peeling of the lower layer part 10 and the circuit layer part 20. That is, the lower layer part 10 connectedly formed on the support substrate 100 has an effect of easily removing the support substrate 100.

Mounting step of the conductive balls 4, dicing step:

The plurality of conductive balls 4 are mounted in the corresponding vias 11. The electronic device mounting the plurality of conductive balls 4 therein is cut along the scribe line 120. FIG. 13 shows the individually separated electronic devices 1. In a dicing step, when a region surrounding the circuit formation region 110 is not the scribe line 120, the region remains without being cut. Through these steps, the electronic device 1 according to the first embodiment of the present invention is manufactured.

In the electronic device 1 according to the first embodiment of the present invention, when the interconnection substrate 2 is formed, the insulating part 12 of the lower layer part 10 unintermittedly exists in a region including a region above the scribe line 120. On the other hand, the insulating part 32 and the insulating part 42 of the circuit layer part 20, which are formed on the lower layer part 10, do not exist above the scribe line 120. That is, the insulating part 32 and the insulating part 42 of the circuit layer part 20 are formed so as not to exist over the entire surface of the support substrate 100. The insulating part 32 and the insulating part 42 shrink during curing, easily causing warp of the support substrate 100. In addition, the insulating parts (the insulating part 12, the insulating part 32 and the insulating part 42) are different from the support substrate 100 in thermal expansion coefficient, easily causing warp of the support substrate 100. However, in the interconnection substrate 2 of the electronic device 1 according to the present invention, only the thin insulating part 12 exists above the scribe line 120. Thus, in a step of curing the insulating part 32 and the insulating part 42, warp of the support substrate 100 due to cure shrinkage of the insulating part 32 and the insulating part 42 can be reduced. Further, in the interconnection substrate 2 of the electronic device 1 according to the present invention, even if heat is applied to the cured insulating parts (the insulating part 12, the insulating part 32 and the insulating part 42), since only the thin insulating part 12 exists above the scribe line 120, warp of the support substrate 100 due to difference between the insulating parts and the support substrate 100 in thermal expansion coefficient can be reduced. That is, in the electronic device 1 according to the first embodiment of the present invention, even when the interconnection substrate 2 is built up on the support substrate 100, warp of the support substrate 100 can be advantageously reduced. As a result, the electronic device 1 can prevent any absorbing error and transporting error in a state for mounting the semiconductor chip 3 and further ensure reliability of interconnection. When warp of the support substrate 100 is large, a device for forcedly suppressing warp is required. However, the electronic device 1 of the present invention can be manufactured without requiring such a device. Since the lower layer part 10 and the circuit layer part 20 are formed stepwise in the manufactured electronic device 1, the electronic device 1 has more mold resin part 5 than an electronic device having no step. Therefore, since the electronic device 1 can increase a proportion of the mold resin part 5 that is harder than the insulating part 12, the insulating part 32 and the insulating part 42, a BGA land can be fixed and breakage of interconnection by stress can be prevented.

(Second Embodiment)

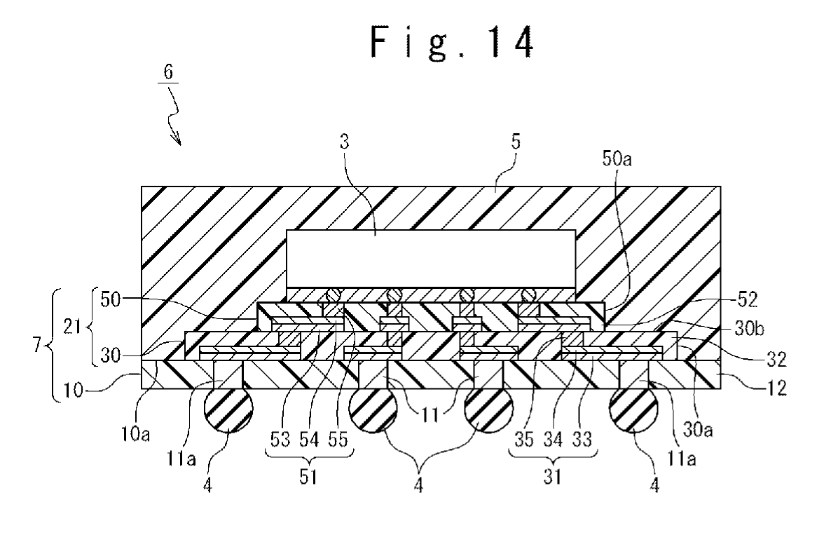

A second embodiment of the present invention will be described. FIG. 14 is a sectional view showing an electronic device 6 according to the second embodiment of the present invention. The same components in the second embodiment as those in the first embodiment are given the same reference numerals. Referring to FIG. 14, the electronic device 6 according to the second embodiment of the present invention includes an interconnection substrate 7, the semiconductor chip 3, the conductive balls 4 and the mold resin part 5.

Like the interconnection substrate 2 in the first embodiment, the interconnection substrate 7 is a multilayer interconnection substrate and includes the lower layer part 10 and a circuit layer part 21. The lower layer part 10 is the same as that in the first embodiment. The lower layer part 10 mounts the plurality of conductive balls 4 thereon and is a lowermost layer in the interconnection substrate 2. The lower layer part 10 includes the plurality of conductive vias 11 and the insulating part 12. The vias 11 are exposed on the upper surface and the lower surface of the lower layer part 10 and the exposed lower sides each are electrically connected to the conductive ball 4. Here, a plurality of outermost vias 11a among the plurality of vias 11 are located on an inner side of the side surface 30a and on an outer side of a side surface 50a. The insulating part 12 covers the plurality of vias 11 so as to expose the vias 11 on the upper surface and the lower surface to protect each of the vias 11. The outer circumferential part 10a on the upper surface of the lower layer part 10 is not covered with the circuit layer part 20 and is covered with the mold resin part 5. The outer circumferential part 10a is located on an outer side of the side surface 30a and the side surface 50a of the circuit layer part 20.

Like the circuit layer part 20, the circuit layer part 21 includes a circuit for connecting the semiconductor chip 3 and an external device (not shown). The circuit layer part 21 is formed on the upper surface of the lower layer part 10 and includes laminated interconnection layers (interconnections 31 and interconnections 51) electrically connected to the plurality of vias 11 exposed on the upper surface of the lower layer part 10, respectively, and laminated insulating layers (an insulating part 32 and an insulating part 52) covering the interconnection layers. The insulating layers of the circuit layer part 21 and the insulating part 12 of the lower layer part 10 are formed of a material having the same thermal expansion coefficient.

The circuit layer part 21 covers the lower layer part 10 except for the outer circumferential part 10a on the upper surface of the lower layer part 10 , and the side surface 30a and the side surface 50a of the circuit layer part 21 are located on an inner side of the outer circumference of the lower layer part 10. The circuit layer part 21 includes the intermediate layer part 30 and an upper layer part 50. The intermediate layer part 30 is the same as that in the first embodiment. However, the intermediate layer part 30 includes an outer circumferential part 30b. The outer circumferential part 30b is an outer circumferential edge of the upper surface of the intermediate layer part 30, which is located on the outer side of the side surface 50a of the upper layer part 50, is not covered with the upper layer part 50 and is covered with the mold resin part 5.

The upper layer part 50 includes the plurality of interconnections 51 and the insulating part 52 covering the plurality of interconnections 51. Each of the plurality of interconnections 51 is an interconnection connected to the interconnection 31 of the intermediate layer part 30 and the semiconductor chip 3, and includes a seed part 53, an interconnection 54 and a connecting terminal 55. That is, the outer circumferential part 10a, the side surface 30a, the outer circumferential part 30b, the side surface 50a and the upper surface of the circuit layer part 21 are formed stepwise. In the interconnection substrate 7, the lower layer part 10 is formed to be thinner than the circuit layer part 21. The thickness of the insulating part on the outermost via 11a is the thickness of the insulating part 32. This thickness is one third of a sum of the thicknesses of the insulating part 32 and the insulating part 52 on the outermost via 11 in FIG. 1.

As shown in FIG. 14, in the electronic device 6 according to the second embodiment of the present invention, in the circuit layer part 21, the intermediate layer part 30 and the upper layer part 50 are formed stepwise. By forming the circuit layer part 21 stepwise, the proportion of the mold resin part 5 can be further increased as compared to the electronic device 1 in the first embodiment, so that effects of fixing the BGA land and enhancing reliability of interconnection can be further increased.

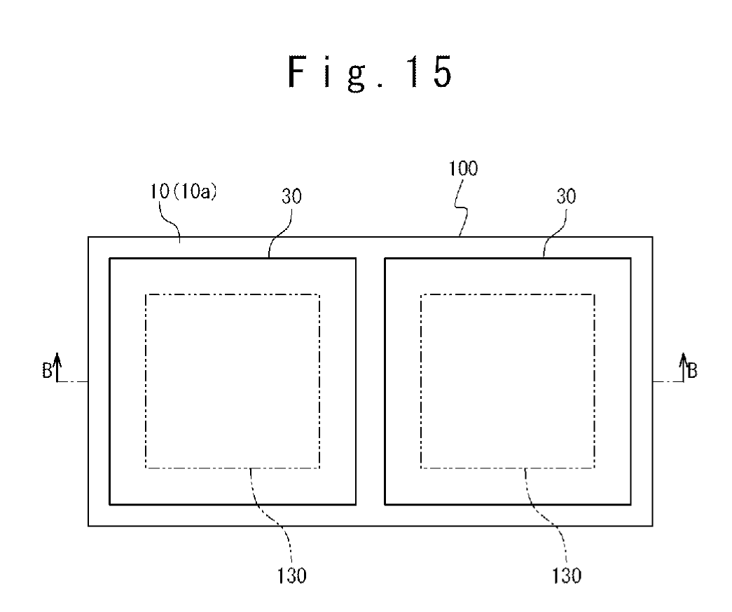

Next, referring to FIGS. 15 to 18, a manufacturing method of the electronic device 6 according to the second embodiment of the present invention will be described. As in the first embodiment, The electronic device 6 according to the second embodiment of the present invention is manufactured through the forming step of the lower layer part 10, the forming step of the intermediate layer part 30, the forming step of the upper layer part 50, the mounting step of the semiconductor chip 3, the resin sealing step, the removing step of the support substrate 100, the mounting step of the conductive balls 4 and the dicing step. Description of the same steps as those in the first embodiment is omitted.

Forming step of the intermediate layer part 30: The intermediate layer part 30 including the plurality of interconnections 31 electrically connected to the plurality of vias 11, respectively, and the insulating part 32 covering the plurality of interconnections 31 is formed on the lower layer part 10 formed as in the first embodiment. FIG. 15 is a plan view showing that the intermediate layer part 30 is formed on the lower layer part 10. Referring to FIG. 15, the lower layer part 10 and the intermediate layer part 30 are formed stepwise and the outer circumferential part 10a of the lower layer part 10 is exposed without being covered with the intermediate layer part 30. A region of the outer circumferential part 10a corresponds to the scribe line 120. A region where the intermediate layer part 30 is formed corresponds to the circuit formation region 110. The electronic device 6 according to the second embodiment of the present invention has a circuit formation region 130 that is smaller than the circuit formation region 110 on the inner side of the region where the intermediate layer part 30 corresponding to the circuit formation region 110 is formed.

Forming step of the upper layer part 50: The upper layer part 50 including the plurality of interconnections 51 electrically connected to the plurality of interconnections 31, respectively, and the insulating part 52 covering the plurality of interconnections 51 is formed on the lower layer part 10 and the intermediate layer part 30. FIG. 16 is a diagram showing that a part of the plurality of interconnections 51 are formed on the intermediate layer part 30 and in the circuit formation region 130 in FIG. 15. FIG. 16 corresponds to a cross-section taken along B-B in FIG. 15. Referring to FIG. 16, a forming method of the plurality of interconnections 51 will be described. The plurality of interconnections 51 are formed in the circuit formation region 130 located on an inner side of the circuit formation region 110 so as to be electrically connected to the corresponding interconnections 31. Describing in detail, the plurality of seed parts 53 are formed to be connected to the corresponding interconnections 31 and interconnections 54 are formed on the plurality of seed parts 53, respectively. The same forming method of the seed parts 53 and the interconnections 54 as that of the interconnections 31 and the interconnections 41 in the first embodiment is exemplified.

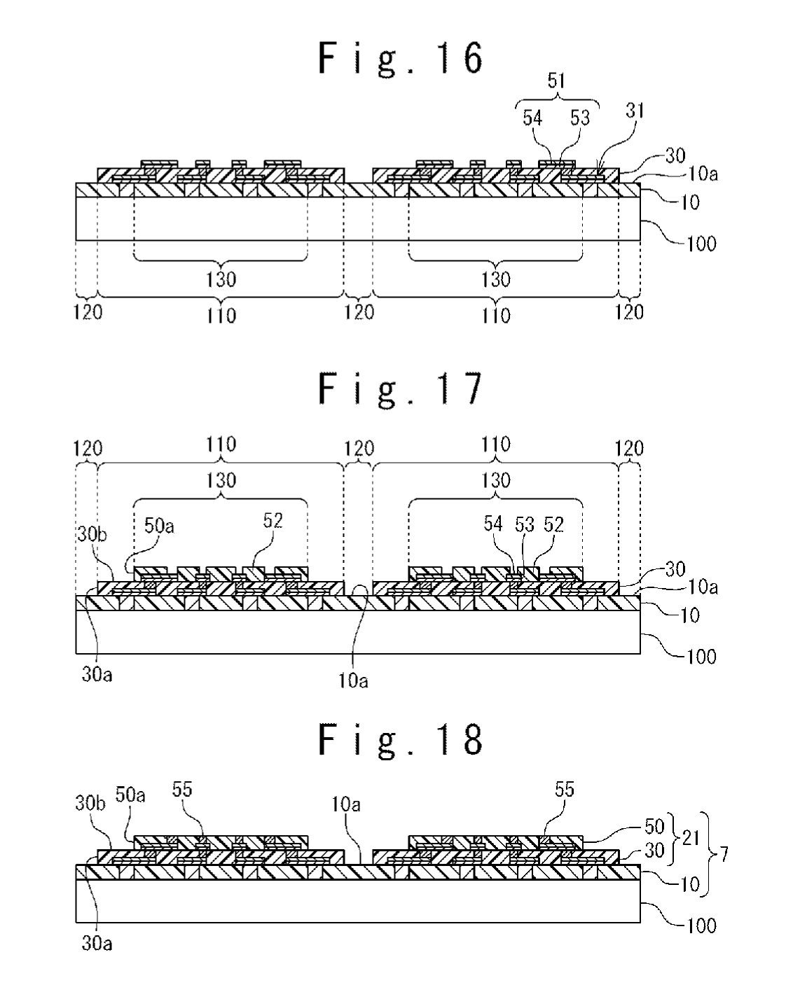

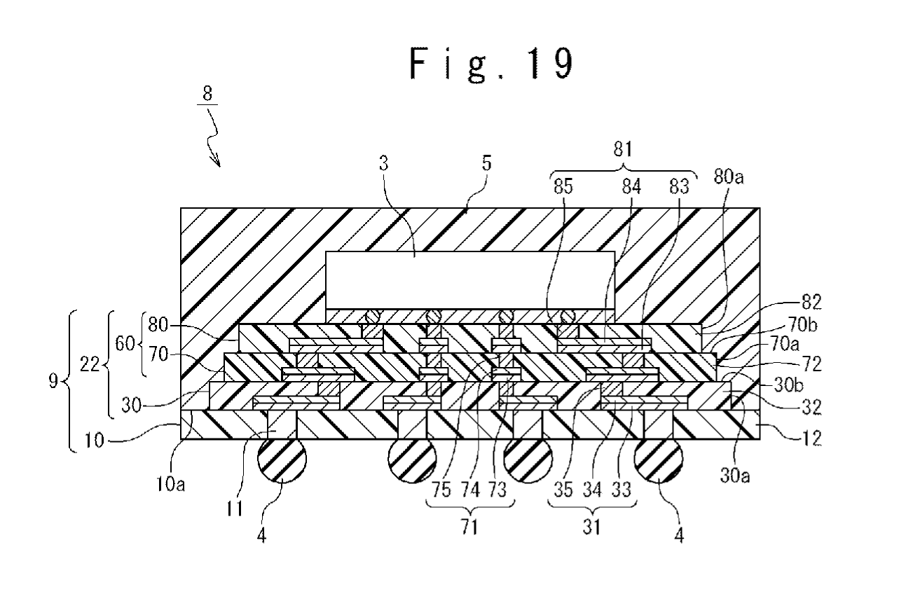

The insulating part 52 made of the same material as the material for the insulating part 12 and the insulating part 32 is formed on the intermediate layer part 30. The insulating part 52 has a plurality of via holes in the circuit formation region 130. FIG. 17 is a sectional view showing that the insulating part 52 is formed so as to cover the plurality of seed parts 53 and the plurality of interconnections 54 in FIG. 16. Referring to FIG. 17, a forming step of the insulating part 52 will be described. The insulating part 52 is formed so as to cover the outer circumferential part 10a on the upper surface of the lower layer part 10 and the intermediate layer part 30. After that, the insulating part 52 located on an outer side of the circuit formation region 130 on the upper surface of the intermediate layer part 30 is removed so as to expose the outer circumferential part 10a and the outer circumferential part 30b. The insulating part 52 is removed so as not to expose the interconnection 51 to the outside. In other words, the region of the insulating part 52 in the outer side of the circuit formation region 130 is removed so as to leave the smallest possible area. However, in order to prevent a void from occurring on the underfill 3a used in a later step, it is preferred that the insulating part 52 is not removed at the place where the semiconductor chip 3 is mounted. When describing an example of a forming method of insulating part 52, the insulating part 52 is applied so as to cover the lower layer part 10, the intermediate layer part 30, the plurality of seed parts 53 and the plurality of interconnections 54 and then, is prebaked. The prebaked insulating part 52 is exposed based on a pattern of the circuit formation region 130 and a pattern of the plurality of connecting terminals 55 connected to the semiconductor chip 3 and is cured through development and postbaking. Referring to FIG. 17, the insulating part 52 does not exist on the outer side of the circuit formation region 130 including the region above the developed scribe line 120, so that the outer circumferential part 10a of the lower layer part 10 and the outer circumferential part 30b of the intermediate layer part 30 are exposed. At this time, like the insulating part 32, the insulating part 52 has a smaller area than the lower layer part 10, which advantageously reduces warp of the support substrate 100 due to cure shrinkage. Especially since the insulating part 52 has a smaller area than the intermediate layer part 30, warp of the support substrate 100 can be reduced more effectively as compared to the first embodiment.

A conductive material such as Ni/Au is filled into the plurality of via holes to form the plurality of connecting terminals 55 in the circuit formation region 130. FIG. 18 is a sectional view showing that the plurality of connecting terminals 55 are formed in FIG. 17. Referring to FIG. 18, the interconnection substrate 7 is built up on the support substrate 100. In the interconnection substrate 7, the lower layer part 10 and the circuit layer part 20 that is smaller than the lower layer part 10 are formed stepwise and the intermediate layer part 30 and the upper layer part 50 that is smaller than the intermediate layer part 30 are formed stepwise. That is, the outer circumferential part 10a, the side surface 30a, the outer circumferential part 30b, the side surface 50a and the upper surface of the upper layer part 50 are formed stepwise. Through the above-mentioned steps, the upper layer part 50 is formed.

In the manufacturing method of the electronic device 6 according to the second embodiment of the present invention, the steps subsequent to the mounting step of the semiconductor chip 3 are the same as those in the first embodiment and therefore, description thereof is omitted.

Like the electronic device 1 according to the first embodiment, the electronic device 6 according to the second embodiment of the present invention has the effect of reducing warp of the support substrate 100 even when the interconnection substrate 2 is built up on the support substrate 100. Especially, in the electronic device 6 according to the second embodiment, since the insulating part 52 of the upper layer part 50 has a smaller area than the intermediate layer part 30, warp of the support substrate 100 can be further reduced. Describing in detail, the insulating part 52 can be removed to an extent that the interconnections 51 are not exposed on an inner side of the outermost vias 11a. As the laminated insulating part becomes smaller, warp of the support substrate 100 is reduced. Further, in the manufactured electronic device 6, in the circuit layer part 21, the intermediate layer part 30 and the upper layer part 50 are formed stepwise. By forming the circuit layer part 21 stepwise, the proportion of the mold resin part 5 can be further increased than that in the electronic device 1 in the first embodiment, so that effects of fixing the BGA land and enhancing reliability of interconnection can be further increased.

(Third Embodiment)

A third embodiment of the present invention will be described. The electronic device 1 according to the first embodiment of the present invention has the interconnection substrate 2 of three-layered structure and the electronic device 6 according to the second embodiment also has the interconnection substrate 7 of three-layered structure. However, the interconnection substrate of the present invention is not limited to the three-layered structure and may be two-layered structure or four or more-layered structure. The third embodiment of the present invention is an embodiment of an interconnection substrate of four-layered structure. FIG. 19 is a sectional view showing an electronic device 8 according to the third embodiment of the present invention. The same component in the third embodiment as those in the first embodiment are given the same reference numerals. Referring to FIG. 19, the electronic device 8 includes an interconnection substrate 9, the semiconductor chip 3, the conductive balls 4 and the mold resin part 5.

Like the interconnection substrate 2 in the first embodiment, the interconnection substrate 9 is a multilayer interconnection substrate and includes the lower layer part 10 and a circuit layer part 22. The lower layer part 10 is the same as that in the first embodiment. The outer circumferential part 10a on the upper surface of the lower layer part 10 is not covered with the circuit layer part 20 and is covered with the mold resin part 5. The outer circumferential part 10a is located on an outer side of the side surface 30a, a side surface 70a and a side surface 80a of the circuit layer part 20.

The circuit layer part 22 includes a circuit for connecting the semiconductor chip 3 to an external device (not shown). The circuit layer part 22 includes laminated interconnection layers (interconnections 31, interconnections 71 and interconnections 81) that are formed on the upper surface of the lower layer part 10 and are electrically connected to the plurality of vias 11 exposed on the upper surface of the lower layer part 10, respectively, and laminated insulating layers (insulating part 32, an insulating part 72 and an insulating part 82) that cover the interconnection layers. The insulating layers of the circuit layer part 22 and the insulating part 12 of the lower layer part 10 are made of a material having the same thermal expansion coefficient.

The circuit layer part 22 covers the lower layer part 10 except for the outer circumferential part 10a on the upper surface of the lower layer part 10. That is, the side surface 30a, the side surface 70a and the side surface 80a of the circuit layer part 22 are located on the inner side of the outer circumferential part 10a of the lower layer part 10. The circuit layer part 22 includes the intermediate layer part 30 and an upper layer part 60. The intermediate layer part 30 is the same as that in the first embodiment.

However, as in the second embodiment, the intermediate layer part 30 includes the outer circumferential part 30b at its outer circumferential edge.

The upper layer part 60 includes a resin interconnection layer 70 and a resin interconnection layer 80. The resin interconnection layer 70 includes the plurality of interconnections 71 and the insulating part 72 covering the plurality of interconnections 71. Each of the plurality of interconnections 71 is an interconnection connected to the interconnection 31 of the intermediate layer part 30 and the resin interconnection layer 80, and includes a seed part 73, an interconnection 74 and a post 75.

The resin interconnection layer 80 includes the plurality of interconnections 81 and the insulating part 82 covering the plurality of interconnections 81. Each of the plurality of interconnections 81 is an interconnection connected to the interconnections 71 of the resin interconnection layer 70 and the semiconductor chip 3, and includes a seed part 83, an interconnection 84 and a connecting terminal 85. The resin interconnection layer 80 is formed on the resin interconnection layer 70 so as to be smaller than the resin interconnection layer 70. Accordingly, the outer circumferential part 10a, the side surface 30a, the outer circumferential part 30b, the side surface 70a, an outer circumferential part 70b, the side surface 80a and an upper surface of the circuit layer part 22 are formed stepwise. Although the intermediate layer part 30, the resin interconnection layer 70 and the resin interconnection layer 80 of the circuit layer part 22 are formed stepwise as in the second embodiment, they may be laminated to have the same size as in the first embodiment. As in the second embodiment, the insulating part 32, the insulating part 72 and the insulating part 82 may be removed so as to have the smallest possible area to the extent the interconnections in each layer are not removed.

In the electronic device 8 according to the third embodiment of the present invention, in the circuit layer part 22, the intermediate layer part 30, the resin interconnection layer 70 and the resin interconnection layer 80 are formed stepwise. By forming the circuit layer part 22 stepwise, like the electronic device 6 in the second embodiment, the electronic device 8 in the third embodiment has the effect of reducing warp of the support substrate 100 even when the interconnection substrate 2 is built up on the support substrate 100. In the electronic device 8 according to the third embodiment of the present invention, since the circuit layer part 22 is laminated so as to be smaller than the lower layer part 10, another layer can be further laminated in the interconnection substrate 9. Since the electronic device 8 according to the third embodiment of the present invention can increase the proportion of the mold resin part 5 even if the interconnection substrate 9 becomes multi-layered, it is possible to increase the effects of fixing the BGA land and enhancing reliability of interconnection. The electronic device 8 according to the third embodiment of the present invention is manufactured according to the manufacturing method described in the first embodiment and the second embodiment and therefore, description thereof is omitted. The above-mentioned electronic devices according to the first to third embodiments of the present invention can be combined so as not to cause any contradiction.

What is claimed is:

1. A manufacturing method of an electronic device comprising:
forming a lower layer part including a conductive via and a first insulating part covering the via on a support substrate; and
forming an intermediate layer part including a first interconnection electrically connected to the via and a second insulating part covering the first interconnection on the lower layer part,
wherein the forming the lower layer part comprises:
forming the first insulating part on a first circuit formation region for forming a circuit and a first region surrounding the first circuit formation region; and
forming the via on the first circuit formation region, and
the forming the intermediate layer part comprises:
forming the first interconnection on the first circuit formation region;
forming a film of the second insulation part to cover the lower layer part; and
removing the second insulating part on the first region such that an outer circumferential part of an upper surface of the lower layer part is exposed.

2. The manufacturing method of the electronic device according to claim 1, further comprising:
forming an upper layer part including a second interconnection electrically connected to the first interconnection and a third insulating part covering the second interconnection on the intermediate layer part,
wherein the forming the upper layer part comprises:
forming the second interconnection on the first circuit formation region;
forming the third insulating part to cover the outer circumferential part of the upper surface of the lower layer part and the intermediate layer part; and
removing the third insulating part on the first region.

3. The manufacturing method of the electronic device according to claim 2, wherein the forming the second interconnection on the first circuit formation region comprises:
forming the second interconnection on a second circuit formation region being inner side than the first circuit formation region, and
the removing the third insulation part on the first region comprises:
removing the third insulating part being outer side than the second circuit formation region on an upper surface of the intermediate layer part such that an outer circumferential part of the upper surface of the intermediate layer part is exposed.

4. The manufacturing method of the electronic device according to claim 3, wherein the via is located on an outer side of the second circuit formation region.

5. The manufacturing method of the electronic device according to claim 2, wherein the second interconnection is a multi-layer interconnection.

6. The manufacturing method of the electronic device according to claim 2, further comprising:
mounting a semiconductor chip electrically connected to the second interconnection on the upper layer part;
covering the outer circumferential part of the upper surface of the lower layer part, the intermediate layer part, the upper layer part, and the semiconductor chip by mold resin;
removing the supporting substrate from the lower layer part;
forming a conductive ball on the via; and
cutting along a scribe line for cutting included in the first region.

7. An electronic device comprising:
a lower layer part including a conductive via and a first insulating part covering the via such that the via is exposed at an upper surface and a lower surface;
a circuit layer part including: a laminated interconnection layer formed on the lower layer part and electrically connected to the exposed upper surface of the via; and a laminated insulating layer covering the interconnection layer;
a semiconductor chip mounted on the circuit layer part and electrically connected to the interconnection layer; and
a mold resin part covering: a first outer circumferential part located at an outer circumferential edge of an upper surface of the lower layer part; the circuit layer part; and the semiconductor chip,
wherein the circuit layer part is formed on an inner side of the lower layer part in a planar view, and
the lower layer part is thinner than the circuit layer part.

8. The electronic device according to claim 7, wherein the circuit layer part comprises:
an intermediate layer part formed on the upper surface of the lower layer part and including: a first interconnection electrically connected to the via; and a second insulating part covering the first interconnection; and
an upper layer part formed on an upper surface of the intermediate part and including: a second interconnection electrically connected to the first interconnection and; a third insulating part covering the second interconnection,
wherein the intermediate layer part comprises:
a second side surface being covered by the mold resin; and
a second outer circumferential part located at an outer circumferential edge on the upper surface of the intermediate layer part on an outer side of a third side surface of the upper layer part and covered by the mold resin, and
the first outer circumferential part, the second side surface, the second outer circumferential part, and the third side surface are formed to be a stepwise shape.

9. The electronic device according to claim 8, wherein the via is located in an inner side than the second side surface, and in an outer side of the third side surface.
